(19) United States
(12) Patent Application Publication
(10) Pub. No.: US 2025/0261357 A1
(43) Pub. Date: Aug. 14, 2025

(54) Memory Circuitry And Methods Used In Forming Memory Circuitry

(71) Applicant: Micron Technology, Inc., Boise, ID (US)

(72) Inventor: Chris M. Carlson, Nampa, ID (US)

(73) Assignee: Micron Technology, Inc., Boise, ID (US)

(21) Appl. No.: 19/007,941

(22) Filed: Jan. 2, 2025

Related U.S. Application Data
(60) Provisional application No. 63/552,776, filed on Feb. 13, 2024.

(51) Int. Cl. H10B 12/00

(52) U.S. Cl. CPC H10B 12/30; H10B 12/03; H10B 12/05

(57) ABSTRACT

Memory circuitry comprises vertically-alternating tiers of insulative material and memory cells. The memory cells individually comprise a capacitor and a horizontally-oriented transistor. Semiconductor material is directly below the vertically-alternating tiers. A lattice structure is within the semiconductor material. The lattice structure comprises insulative first vertical walls and insulative second vertical walls that cross laterally through one another below a top of the semiconductor material. The lattice structure comprises an insulative horizontal blanket layer that is vertically between and spaced from the top and a bottom of the semiconductor material. At least one of a plurality of the first vertical walls or a plurality of the second vertical walls are individually narrower at a top of the insulative horizontal blanket layer than at a bottom of the insulative horizontal blanket layer. Other embodiments, including methods, are also disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-7 are diagrammatic cross-sectional views of portions of a construction that will comprise circuitry in accordance with an embodiment of the invention.

FIGS. 8-38 are diagrammatic sequential sectional and/or enlarged views of the construction of FIGS. 3-7, or portions thereof or alternate and/or additional embodiments, in process in accordance with some embodiments of the invention.

### DETAILED DESCRIPTION OF EXAMPLE EMBODIMENTS

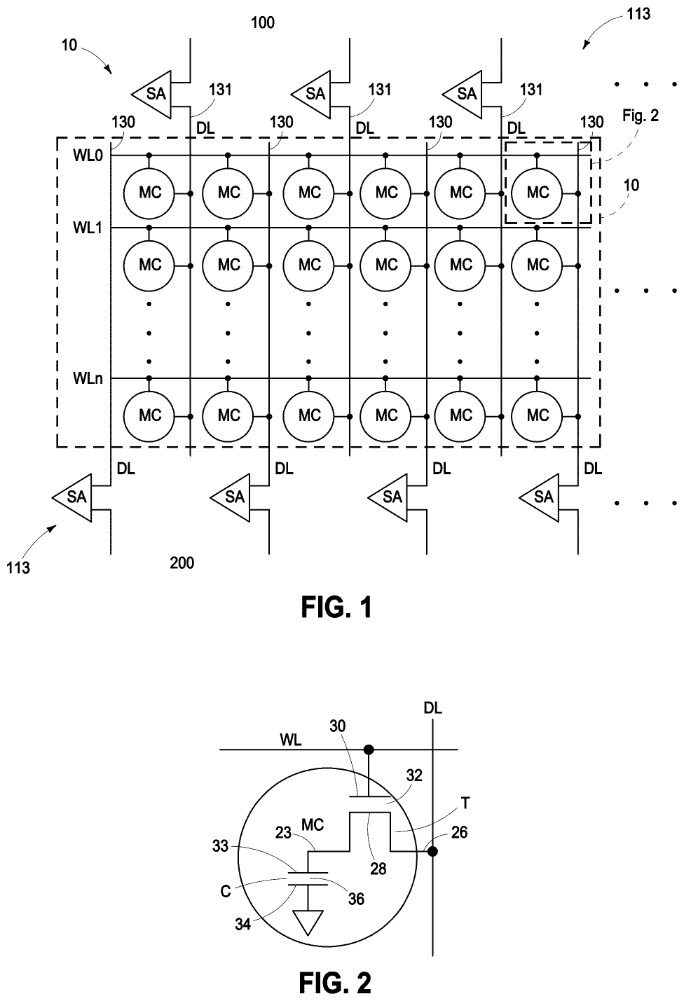

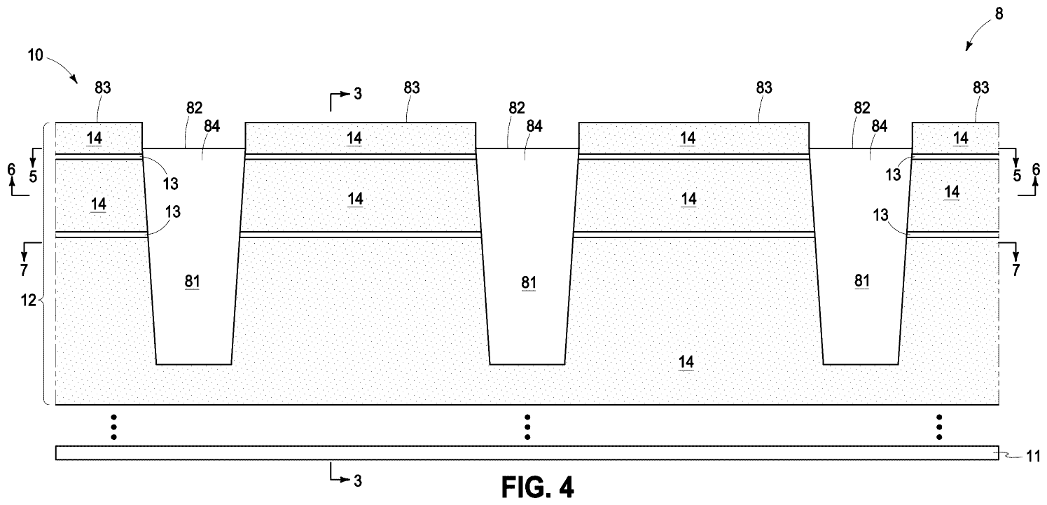

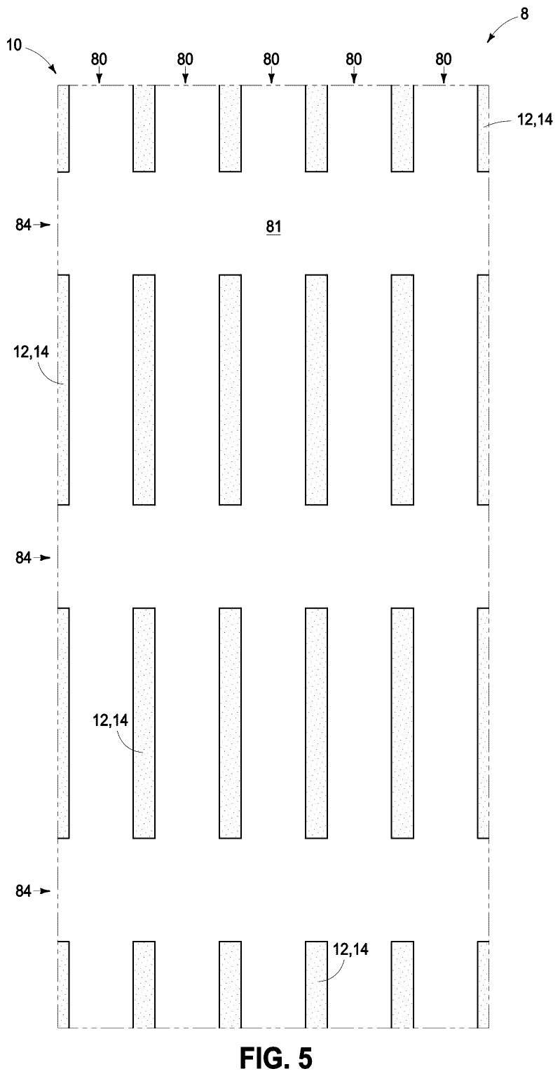

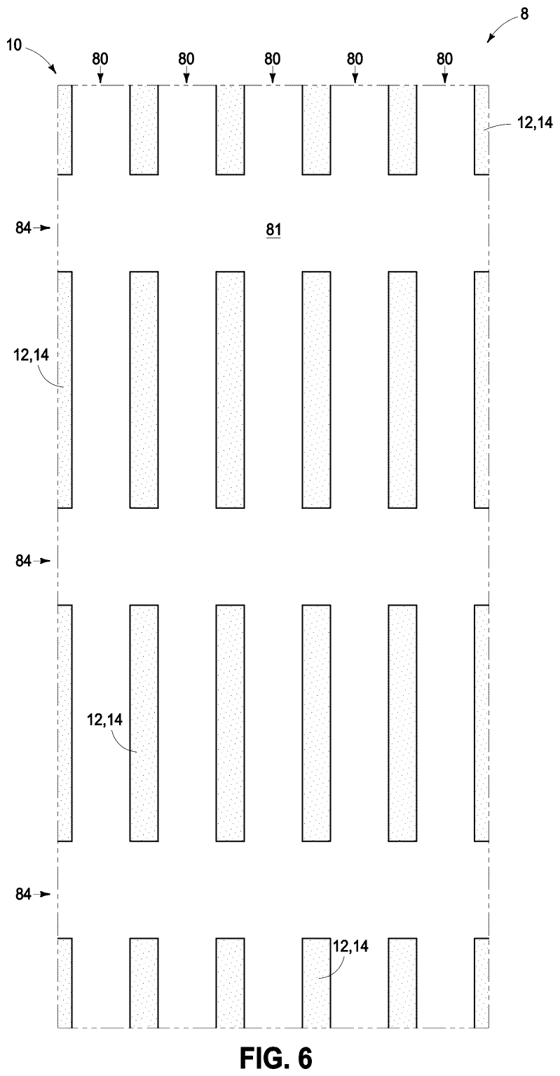

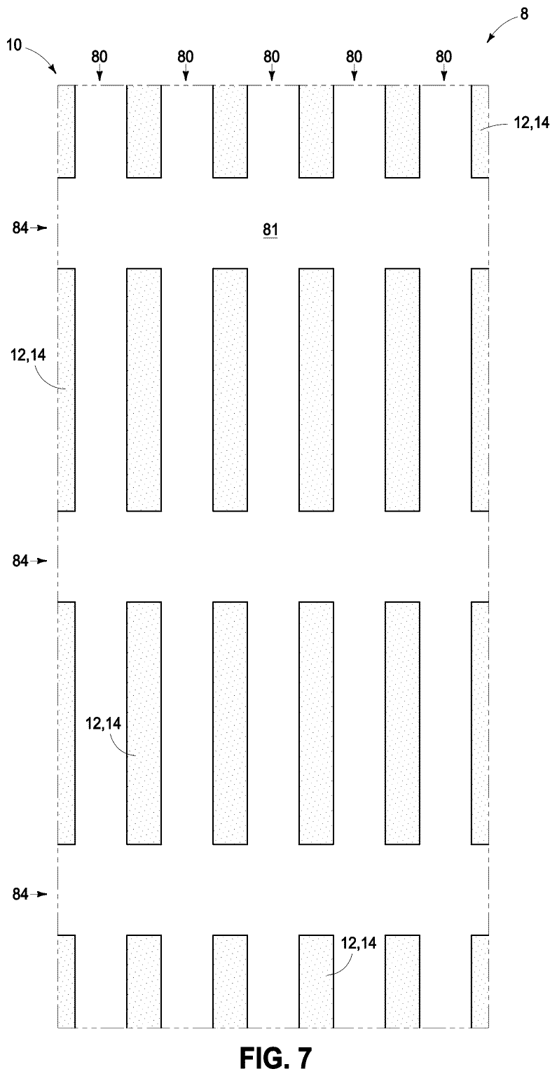

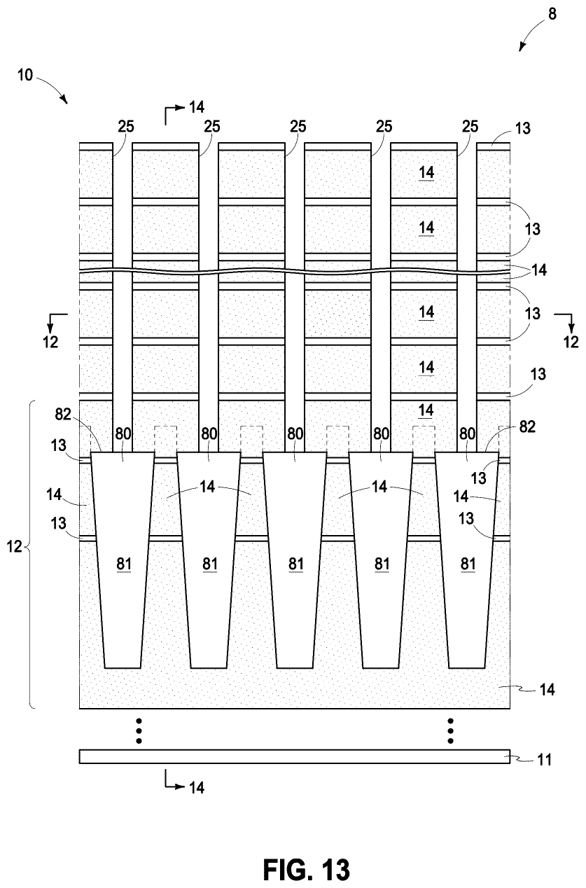

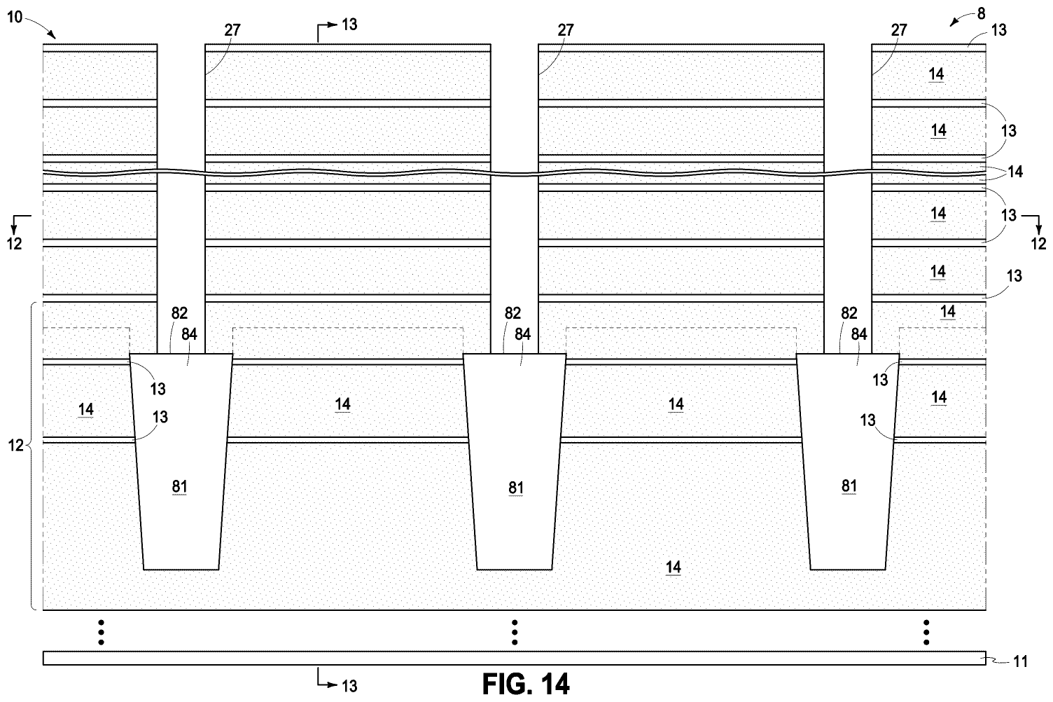

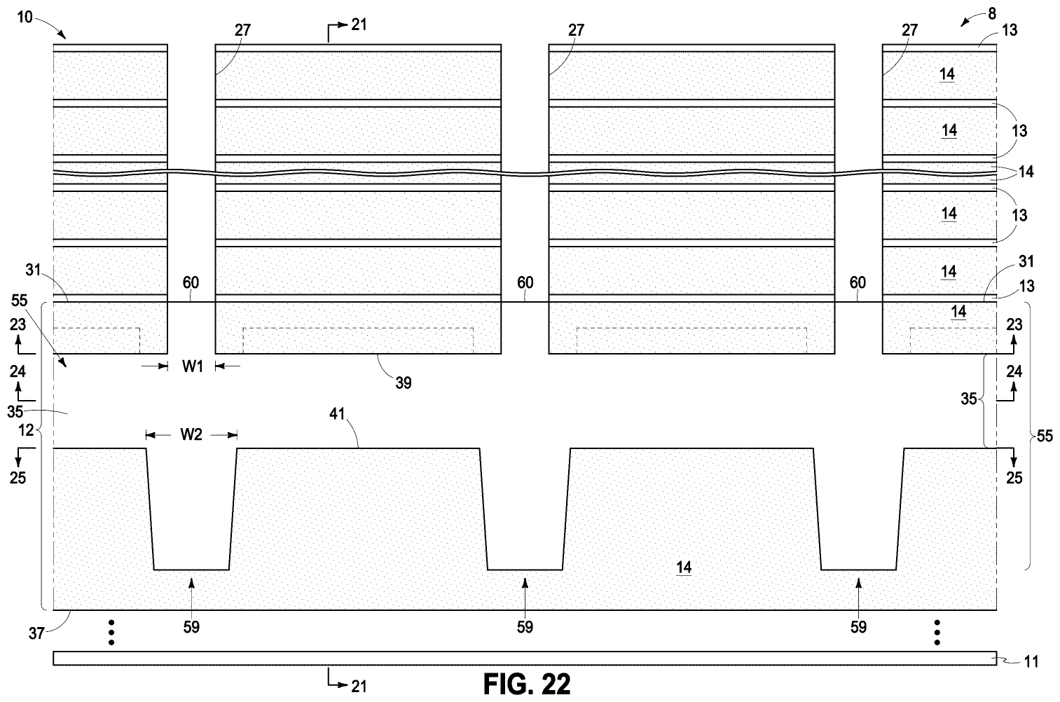

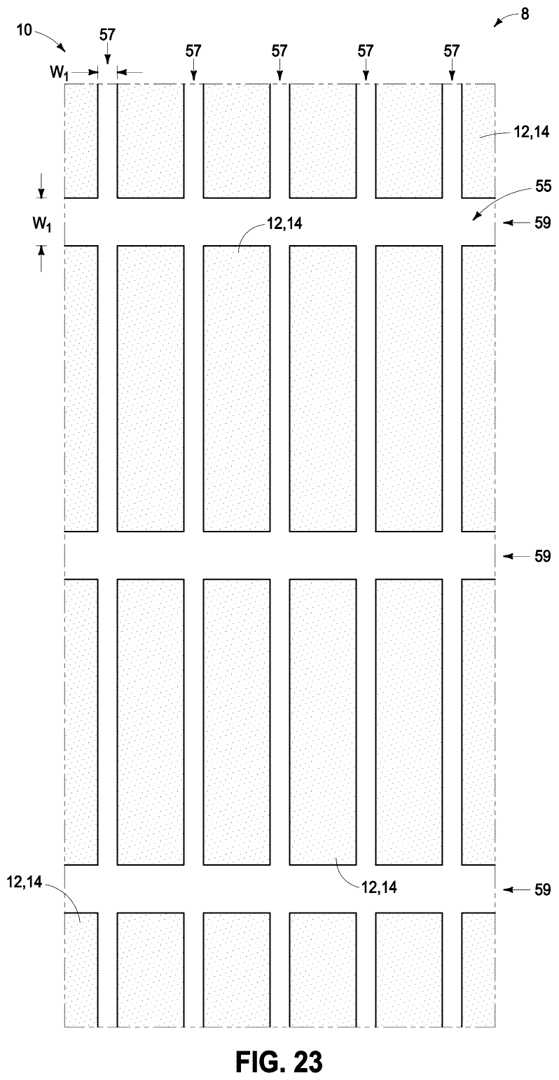

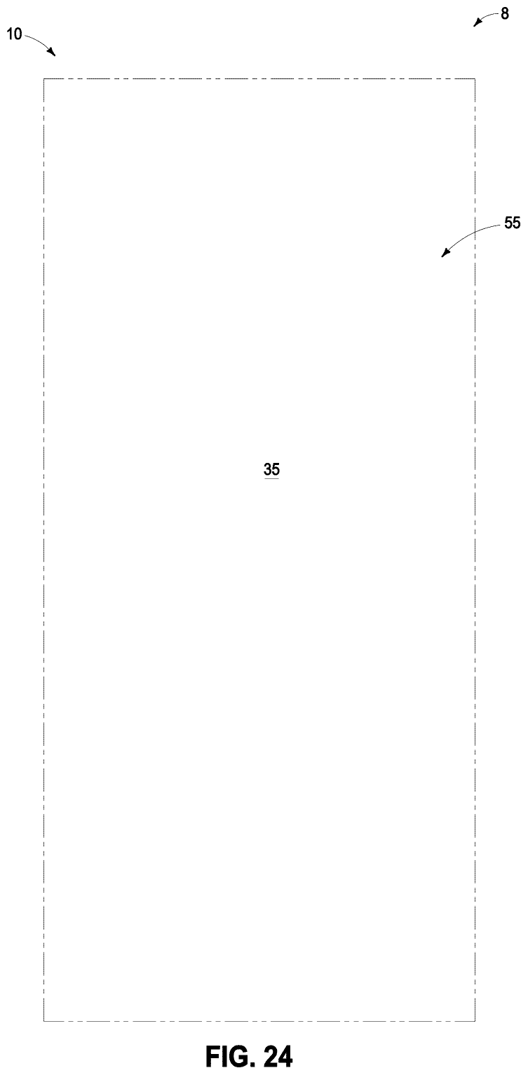

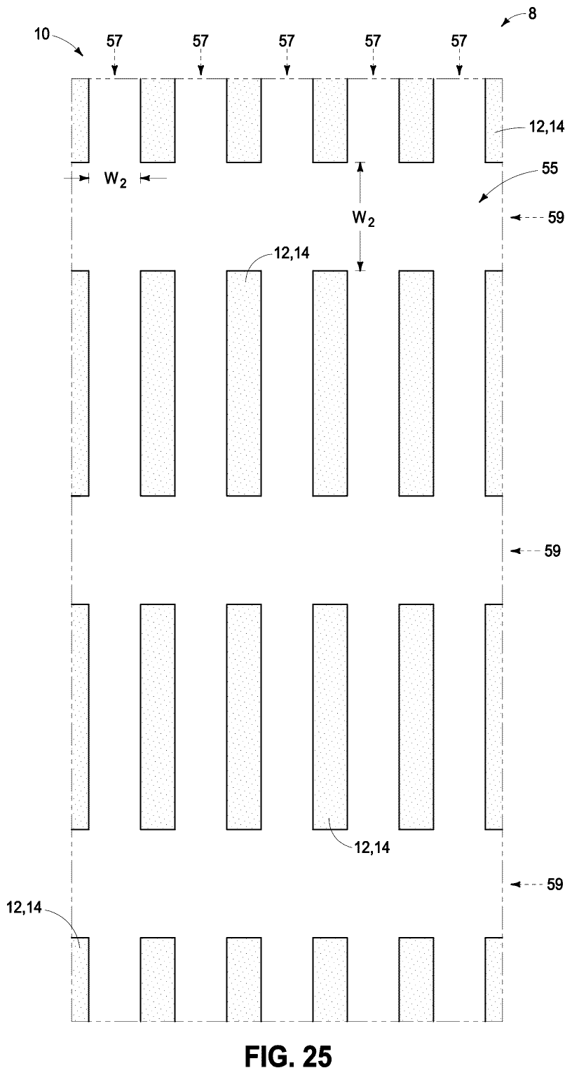

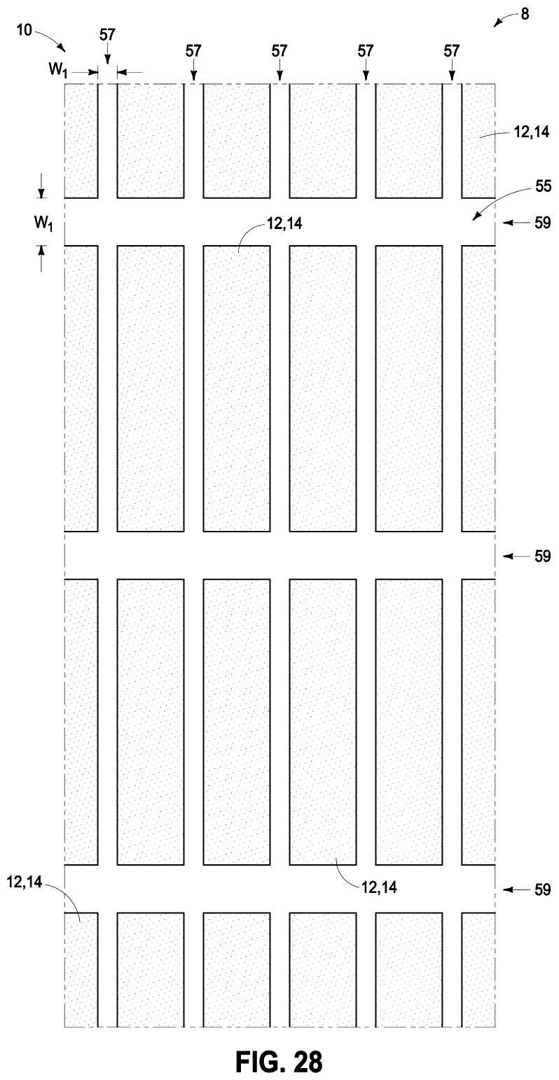

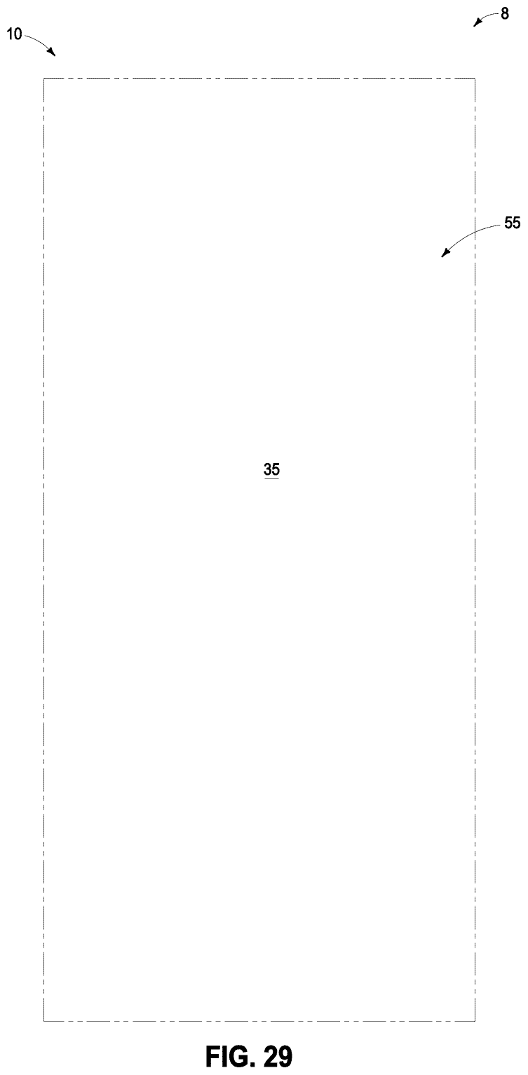

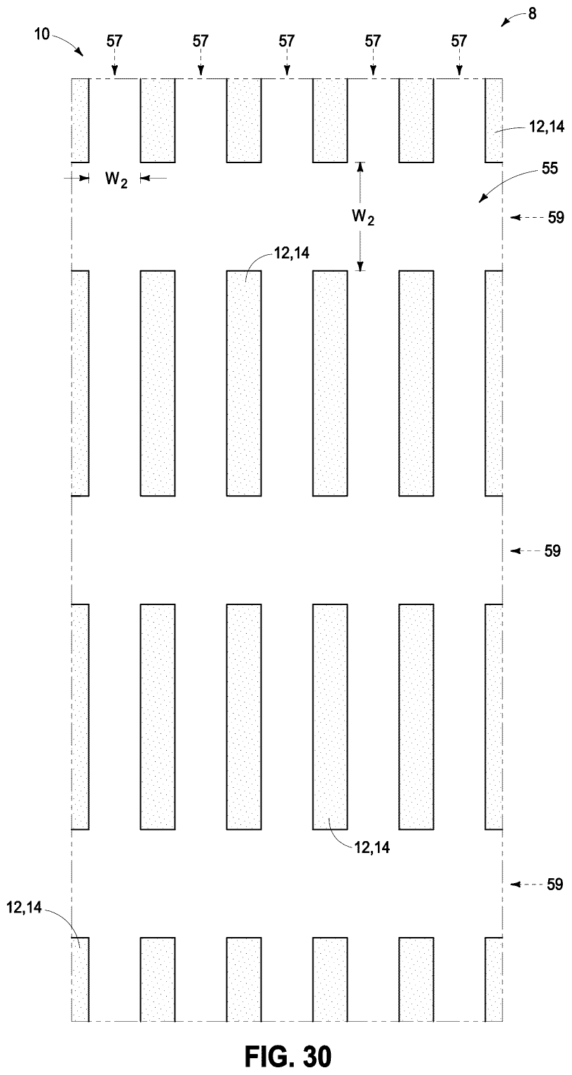

Embodiments of the invention encompass memory circuitry (e.g., DRAM) having vertically-alternating tiers of insulative material and memory cells, with the memory cells individually comprising a capacitor and a horizontally-oriented transistor. Embodiments of the invention also encompass methods used in forming such memory circuitry. Example method embodiments are first described with reference to FIGS. 1-30.

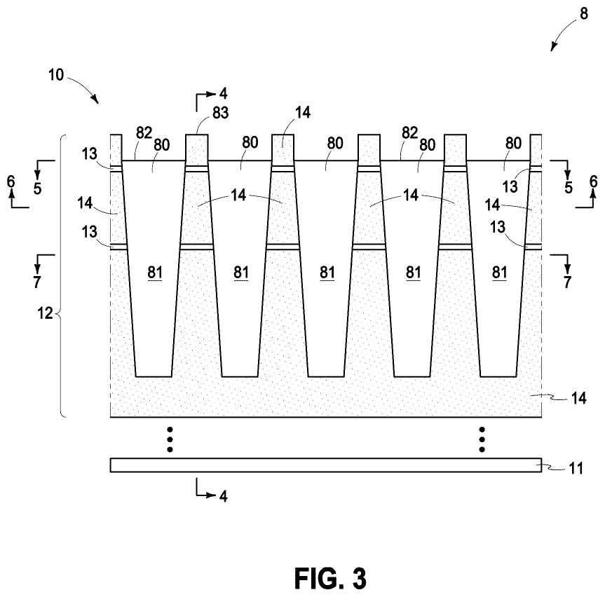

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part of) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Non-schematic structure embodiments as shown herein in FIG. 3+ have the wordlines/access lines running horizontally and the digitlines/sense lines running vertically. This could be reversed or other orientations used. Further, and by way of example only, sense amps SA could be on only one side or all directly above or directly below memory array area 10.

Referring to FIGS. 3-7, an example fragment of a substrate construction 8 comprising array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIG. 3-7-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Semiconductor material 12 is above base substrate 11. In one embodiment, semiconductor material 12 comprises two vertically-spaced layers of silicon-germanium material 13 having silicon material 14 vertically there-between. Example silicon-germanium material 13 is Si₁₋ₓGeₓ, and which may include one or more additional elements. Example silicon material 14 is elemental monocrystalline or polycrystalline silicon and which may include one or more additional elements. Materials 14 and 13 are ideally of etchably-different compositions relative one another. Example semiconductor material 12 is shown as comprising silicon material 14 below the lowest layer of silicon-germanium material 13 and silicon material 14 above the highest layer of silicon-germanium material 13. If, by way of example, base substrate 11 is bulk monocrystalline silicon, silicon material 14 below the lowest layer of silicon-germanium material 13 may be an upper or uppermost portion of such bulk monocrystalline silicon.

Parallel and spaced lower walls 80 have been formed in semiconductor material 12. Lower walls 80 in some embodiments may be considered as being a series of first etch-stop walls 80. Individual lower walls 80 comprise wall material 81 and have a top 82 that is spaced below a top 83 of semiconductor material 12. In one embodiment, parallel and spaced lower walls 84 have also been formed in semiconductor material 12. Lower walls 84 may be considered as being a series of second etch-stop walls 84 that individually cross first etch-stop walls 80 (e.g., orthogonally). Walls 80 and/or 84 may taper laterally inward moving deeper into semiconductor material 12 (as shown). Individual lower walls 84 comprise wall material 81 and have a top 82 that is spaced below top 83 of semiconductor material 12. If both walls 80 and 84 are included, wall materials thereof need not be of the same composition but ideally are. If both walls 80 and 84 are included, such may be formed simultaneously or either before the other if not simultaneously. An example manner of forming walls 80 and/or 84 comprises etching corresponding trenches into semiconductor material 12, overfilling such with material(s) 81, planarizing material(s) 81 back at least to silicon material 14 that is above the highest layer of silicon-germanium material 13 (when present), and followed by wet-etching such back to produce the example construction as shown. In one embodiment, wall material(s) 81 and walls 80 and/or 84 are insulative (e.g., comprising silicon dioxide and/or silicon nitride). In one embodiment, wall material(s) 81 and walls 80 and/or 84 are at least one of conductive or semiconductive (e.g., comprising metal material or germanium, respectively). In one embodiment, at least some material of walls 80 and/or 84 remains in the finished-circuitry construction and in another embodiment none of walls 80 and/or 84 remains in the finished-circuitry construction.

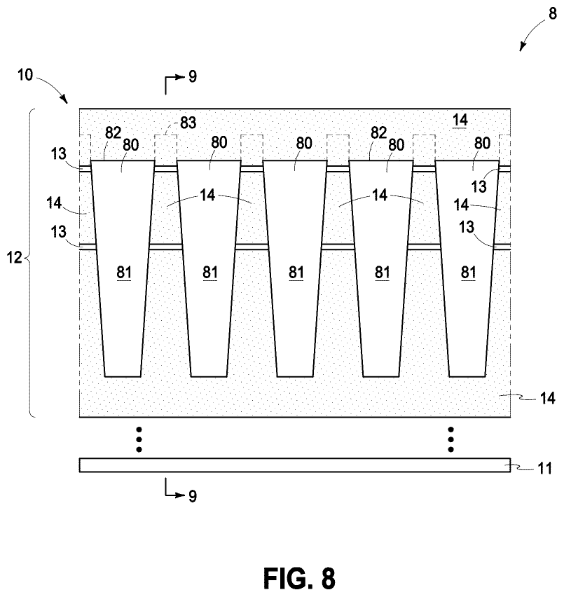

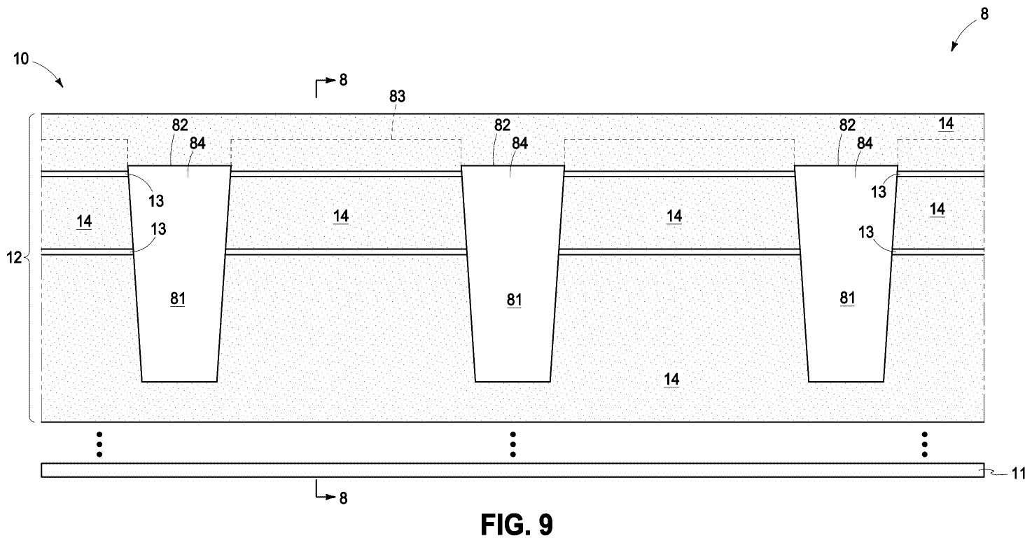

Referring to FIGS. 8 and 9, semiconductive material has been epitaxially formed from semiconductor material 12 to cover over individual lower walls 80 and/or 84. In one embodiment and as shown, such epitaxially-formed semiconductive material comprises silicon material 14. Additional or alternate semiconductor materials may be epitaxially formed (not shown; e.g., silicon-germanium material 13). An example manner of epitaxially forming silicon material 14 includes using SiH₄, Si₂H₆, H₂SiCl₂, HCl, and Cl₂ as precursors at 300° C. to 1,500° C. and 100 mTorr to 100 Torr. The covering-semiconductive material (e.g., silicon material 14) will also form atop semiconductor material 12 (effectively thickening semiconductor material 12) and such may be planarized back at least some as shown.

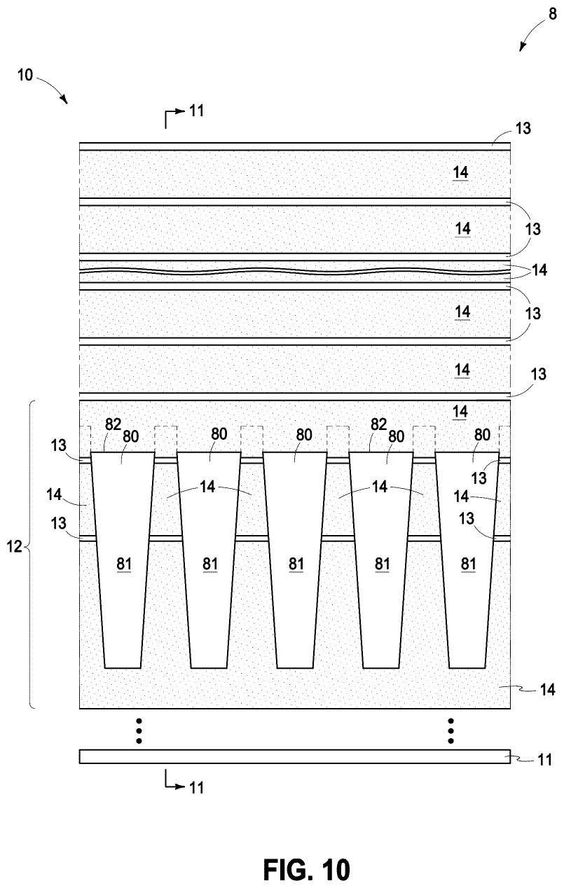

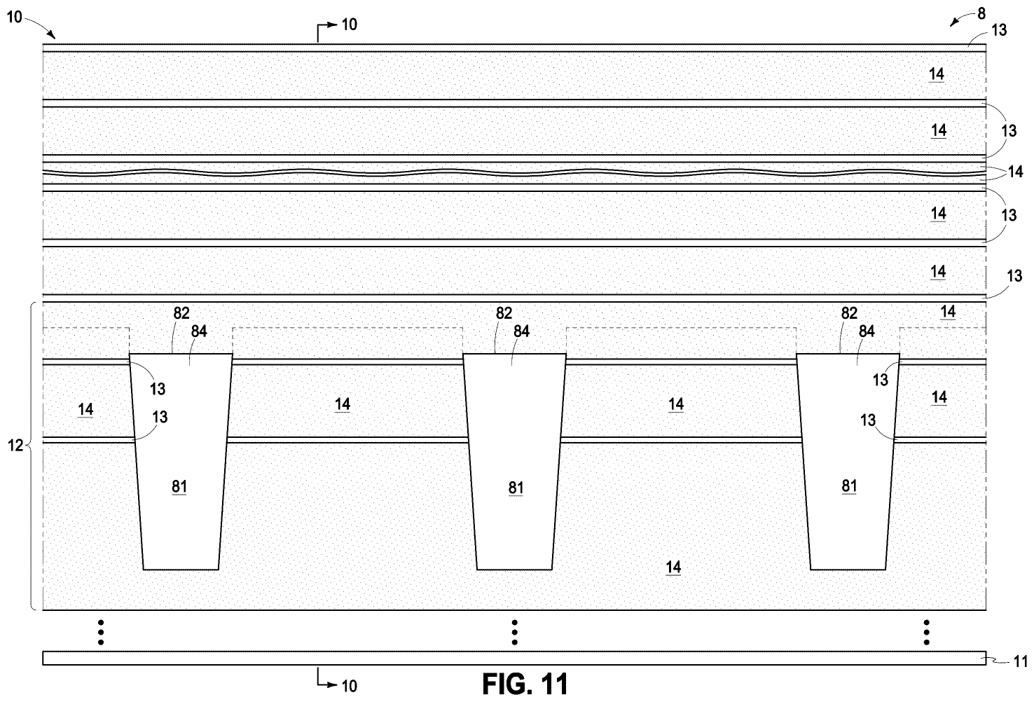

Referring to FIGS. 10 and 11, vertically-alternating layers comprising silicon material 14 and silicon-germanium material 13 have been epitaxially formed directly above semiconductor material 12 and semiconductive-material-covered lower walls 80 and/or 84 (e.g., using GeH₄ as the germanium source in addition to the above precursors when epitaxially forming silicon-germanium material 13).

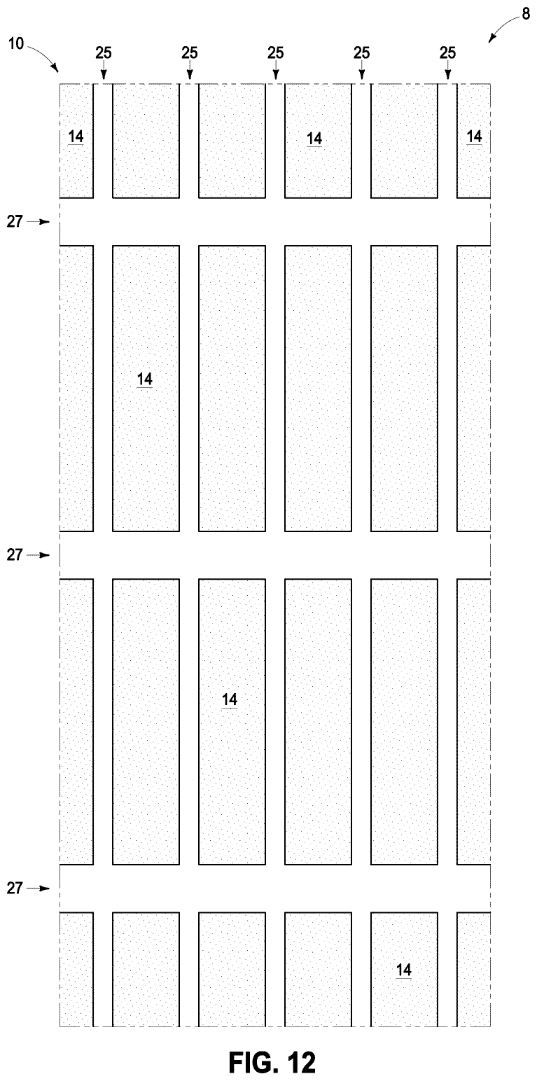

Referring to FIGS. 12-14, parallel and spaced trenches 25 have been etched through the vertically-alternating layers (and the epitaxially-formed semiconductive material when present), with trenches 25 individually being directly above and longitudinally along one of individual walls 80. Trenches 25 are so etched to individual walls 80 using wall material 81 of individual walls 80 as an etch stop during such etching. Etching may stop atop walls 80/wall material 81 (as shown) or may occur into walls 80/wall material 81 (not shown). Parallel and spaced trenches 27 may be additionally or alternately etched through the vertically-alternating layers, with trenches 27 individually being directly above and longitudinally along one of individual walls 84. Such trenches 27 when so etched are etched to individual walls 84 using wall material 81 thereof as an etch stop during such etching. Etching may stop atop walls 84/wall material 81 (as shown) or may occur into walls 84/wall material 81 (not shown). Trenches 25 and/or 27 may be formed, for example, using openings in photoresist and/or hard-masking material (neither being shown) during such etching. Etching chemistry would likely be changed during such etching depending on whether etching through silicon material 14 or silicon-germanium material 13, with such last-etching thereof stopping atop or within wall material(s) 81 of walls 80 and/or 84. Trenches 25 and 27 when both are formed may be done so simultaneously or either before the other. Trenches 25 and/or 27 may taper laterally inward moving deeper into the construction (not shown). Ideally, a bottom (at least) of individual trenches 25 and/or 27 is narrower than the top of the individual lower wall 80 and/or 84 to which such individual trench 25 and/or 27 is etched (e.g., to hopefully avoid over-etch laterally of lower walls 80 and/or 84 into silicon material 14).

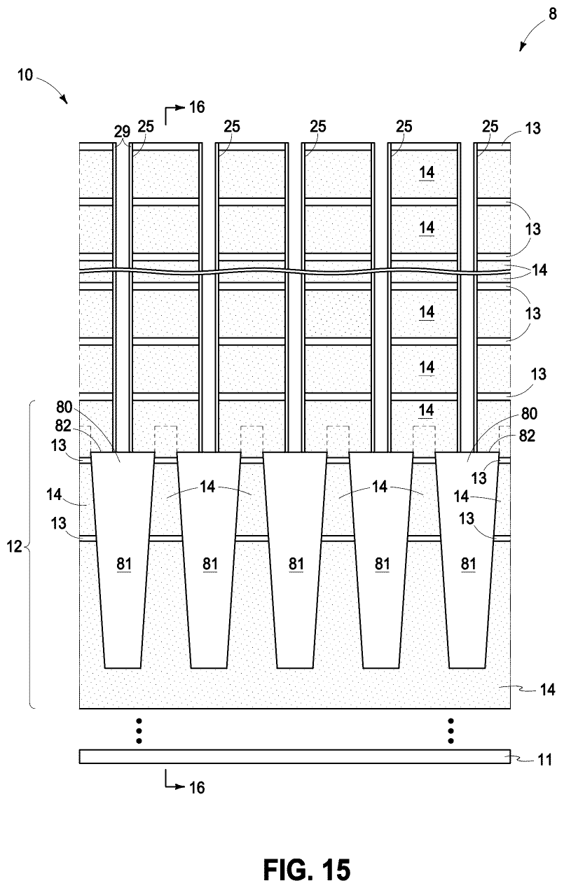

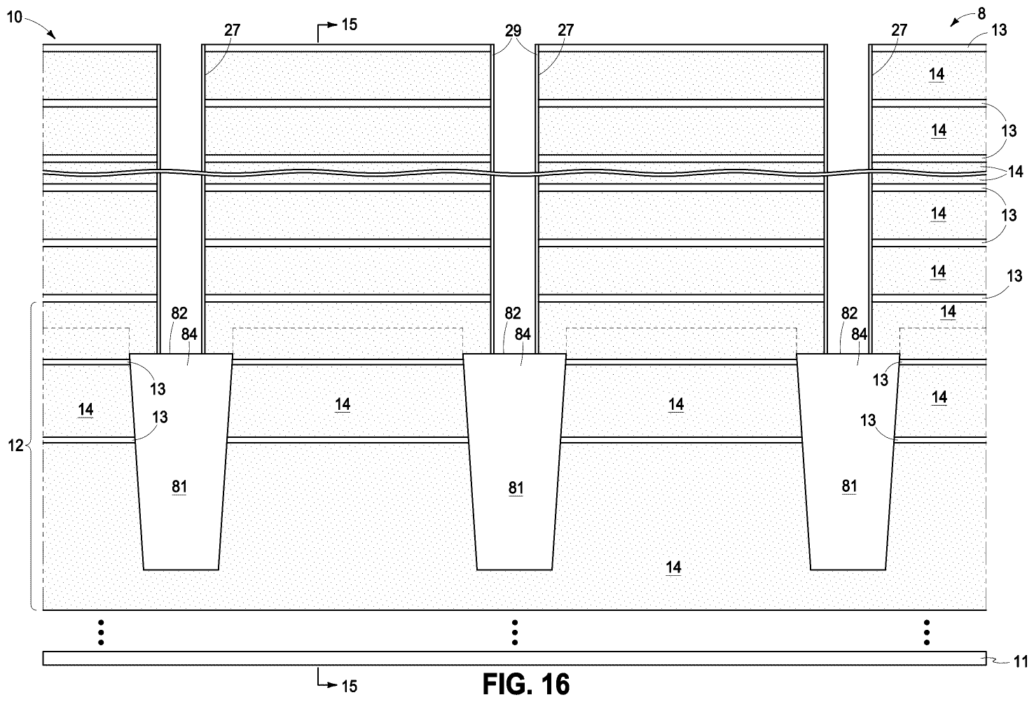

Referring to FIGS. 15 and 16, and in some embodiments, an insulative liner 29 (e.g., silicon nitride) has been formed in trenches 25 and/or 27, followed by example punch-etching thereof to substantially remove such from being over horizontal surfaces. Some etching may occur into material 81 (not shown) during such punch-etching. Insulative liner 29 is ideally of an etchably-different composition from those of materials 13, 14, and 81.

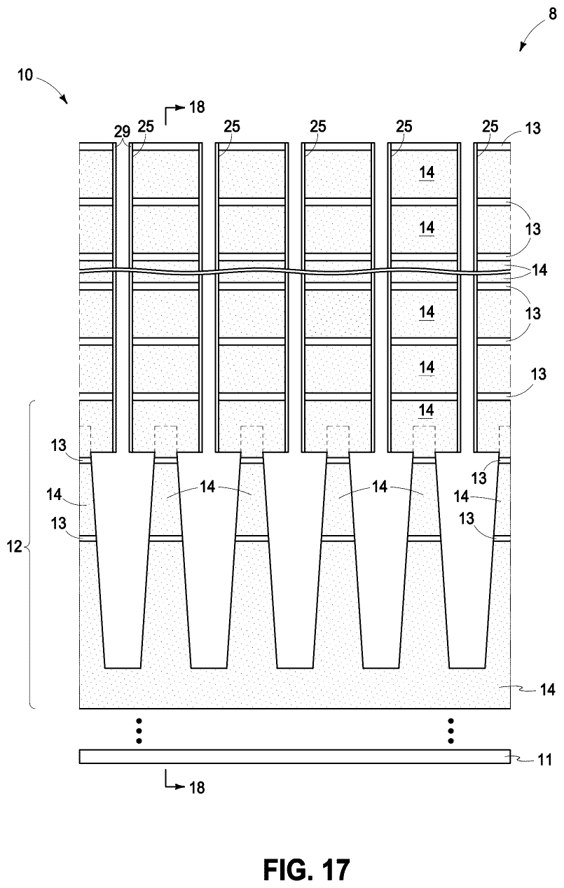

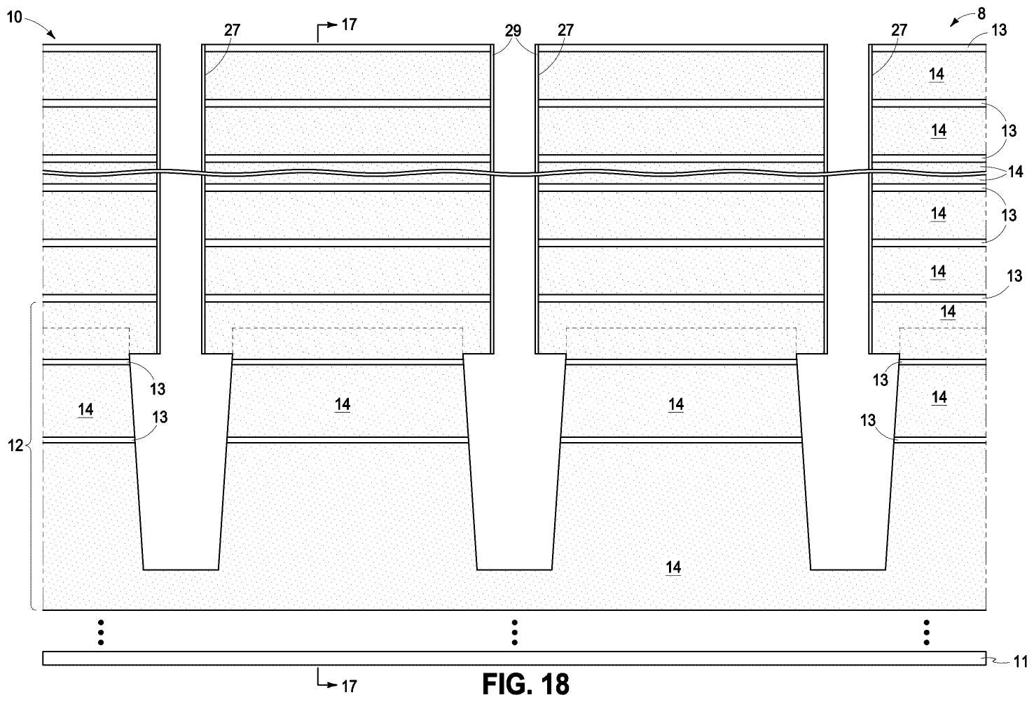

Referring to FIGS. 17 and 18, and in some embodiments, all of wall material(s) 81 and walls 80 and/or 84 (none of such thereby being shown) have been removed through trenches 25 and/or 27 (e.g., by isotropic etching).

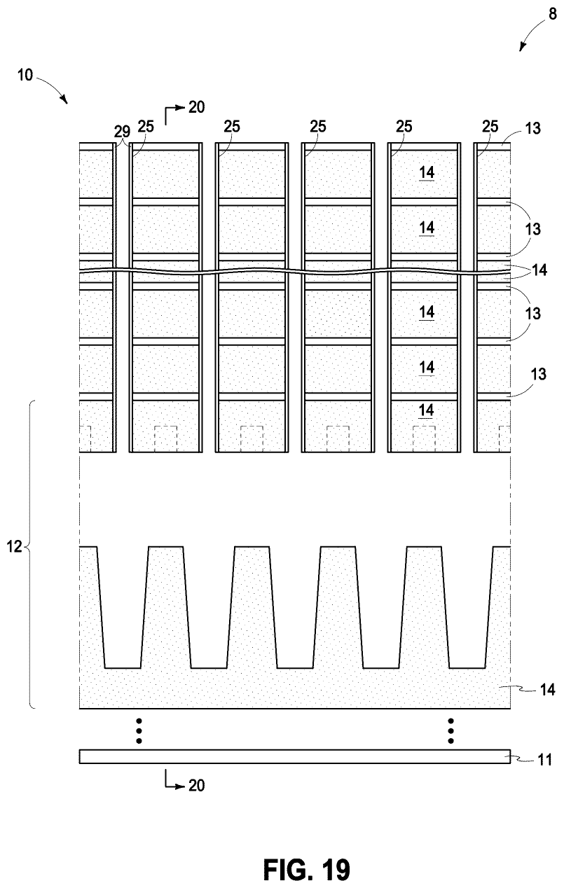

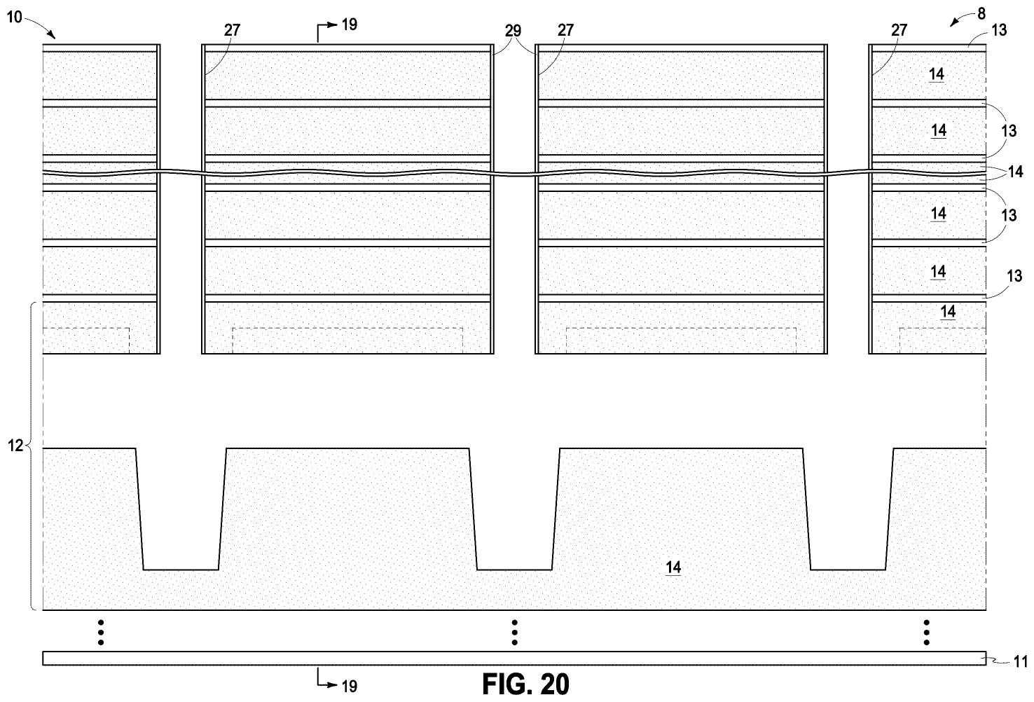

Referring to FIGS. 19 and 20, and in some embodiments, the two vertically-spaced layers of silicon-germanium material 13 as shown in FIGS. 3-18 have been etched away (such material 13 thereof thereby no longer being shown) selectively relative to silicon material 14 vertically there-between. This has been followed by etching away silicon material 14 that was vertically between such two vertically-spaced layers of silicon-germanium material 13 (such silicon material 14 thereby no longer being shown). Void space below what was the lowest layer of silicon-germanium material 13 where walls 80 and/or 84 were (if removed) may be widened thereby (not shown). Alternately, and by way of example only, wall material 81 could be etched downwardly yet still to remain below such lowest layer of silicon-germanium material 13 at least at this point of processing to preclude such widening.

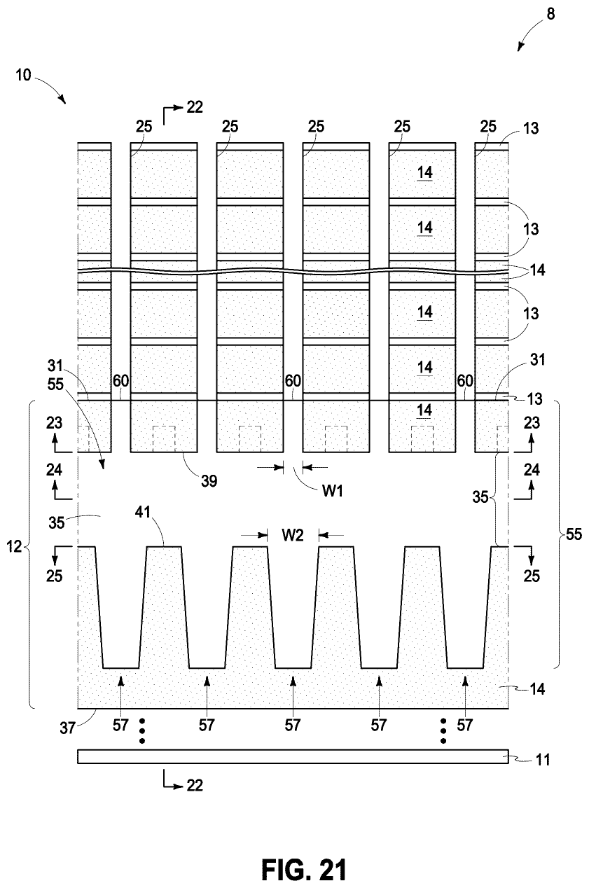

Referring to FIGS. 21-25, liner 29 (not shown) has ideally been removed and a lattice structure 55 has been formed within semiconductor material 12. Lattice structure 55 comprises insulative first vertical walls 57 and insulative second vertical walls 59 that cross laterally through one another below a top 31 of semiconductor material 12. Example lattice structure 55 is shown as having a top 60 that is elevationally coincident with top 31, although such may be higher or lower than top 31. Lattice structure 55 comprises an insulative horizontal blanket layer 35 where the two vertically-spaced layers of silicon-germanium material 13 and the silicon material 14 there-between, as referred to above, were. Insulative horizontal blanket layer 35 is vertically between and spaced from top 31 and a bottom 37 of semiconductor material 12. Walls 57, walls 59, and layer 35 are ideally of the same insulative composition, for example silicon dioxide. Such may be formed, by way of example, by chemical vapor deposition or atomic layer deposition within trenches 25 and/or 27, followed by etching such back as shown. Regardless, at least one of a plurality of first vertical walls 57 (not necessarily each and every one of first vertical walls 57) or a plurality of second vertical walls 59 (not necessarily each and every one of second vertical walls 59) are individually narrower (through its shortest straight-line horizontal dimension; e.g., W₁) at a top 39 of insulative horizontal blanket layer 35 than at a bottom 41 of insulative horizontal blanket layer 35 (e.g., W₂, being longer/greater than W₁). If etching into wall material 81 occurred in the processing shown by one or both of FIGS. 12-14 or FIGS. 15 and 16 (neither being shown), W₁ may be longer than shown, but may still be shorter than W₂.

Referring to FIGS. 2 and 26-30, and after at least etching trenches 25 and/or 27, silicon-germanium material 13 has been removed (no longer shown; e.g., by etching) selectively relative to silicon material 14, and in one embodiment with such silicon material 14 during such removing or subsequently being at least partially thinned, for example in manners not material to the inventions disclosed herein (as shown; e.g., as shown in Micron Technology's U.S. Patent Application Publication Nos. 2022/0254784, 2022/0130834, U.S. Pat. No. 11,342,218, etc.). Vertically-alternating tiers 20 and 22 of insulative material 24 (e.g., silicon dioxide) and memory cells MC, respectively, have then been formed.

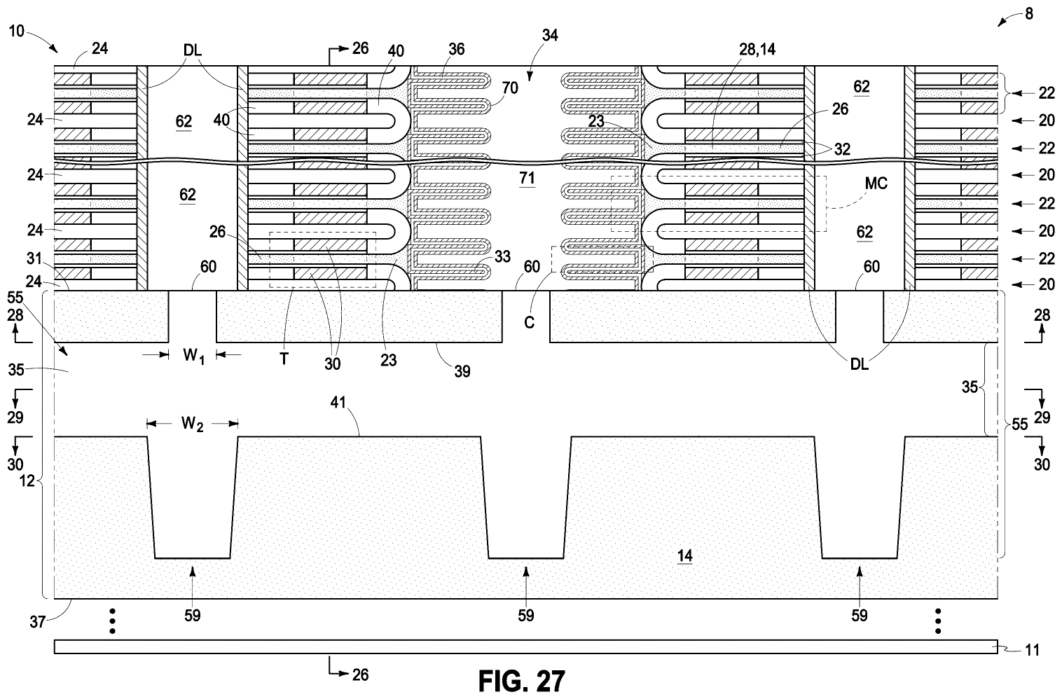

Memory cells MC individually comprise a capacitor C and a horizontally-orientated transistor T having a channel/channel material 28 comprising epitaxially-formed silicon material 14. Example transistor T comprises source/drain regions 23 and 26 (indicated with heavier stippling than channel material 28) having channel material 28 laterally there-between. Regions 23, 26, and 28 of different immediately-horizontally-adjacent memory cells MC into and out of the plane of the page upon which FIG. 27 lies in a common memory-cell tier 22 may be isolated relative one another by insulative material (not shown). Transistor T also comprises a gate 30 (e.g., gate-all-around the channel; e.g., conductive metal material) having a gate insulator 32 (e.g., dielectric or ferroelectric) between at least channel material 28 and gate 30. An example insulator 40 (e.g., silicon nitride) is laterally against lateral sides/edges of gates 30. Source/drain regions 23 and 26 are individually shown as having a lateral edge that is laterally-coincident with a lateral edge of gate 30, although there may be a dopant-concentration gradient between channel material 28 and a highest-dopant concentration within source/drain regions 23 and/or 26. Additionally and/or alternately, source/drain regions 23 and/or 26 may include an LDD region, a halo region, etc. (neither being shown). Example capacitor C comprises a storage-node electrode 33, a common cell plate 34 (e.g., comprising conductive metal material 70 and conductively-doped polysilicon 71), and a capacitor insulator 36 there-between (e.g., dielectric or ferroelectric). Source/drain region 23 of transistor T is directly electrically coupled with and/or may be considered as a part of storage-node electrode 33. Source/drain region 26 of transistor T is directly electrically coupled with a digitline DL, with example insulator 62 (e.g., silicon dioxide and/or silicon nitride) being in a trench and laterally between proximate digitlines DL as shown. Digitlines DL of different immediately-horizontally-adjacent memory cells MC into and out of the plane of the page upon which FIG. 27 lies in a common memory-cell tier 22 may be isolated relative one another by insulative material (not shown). In one embodiment and as shown, walls 80 and/or 84 (neither being shown) are removed before forming vertically-alternating tiers 20 and 22 of insulative material 24 and memory cells MC, with in one such embodiment such walls 80 and/or 84 being removed before removing silicon-germanium material 13 selectively relative to silicon material 14.

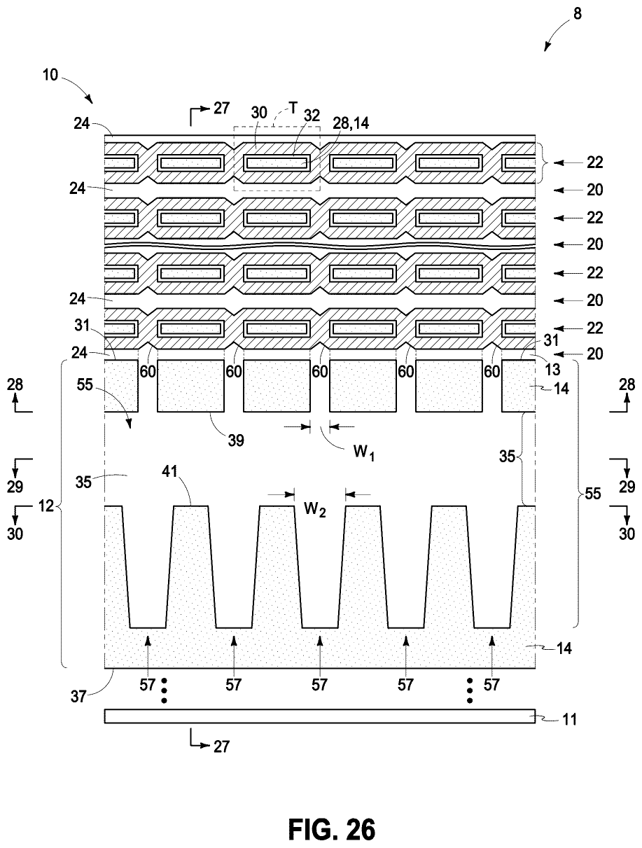

FIGS. 26-30 show but one example embodiment wherein each/both of the plurality of first vertical walls 57 and the plurality of second vertical walls 59 are individually narrower at top 39 of insulative horizontal blanket layer 35 than at bottom 41 thereof. Alternately, only one of such plurality of first vertical walls 57 or plurality of second vertical walls 59 could have such attribute. Further, as alluded to above and regardless, not each and every wall 57 and/or not each and every wall 52 need have such W₁/W₂ relationship as long as at least some plurality of walls 80 or some plurality of walls 84 have such W₁/W₂ relationship.

Some embodiments of the invention contemplate proceeding immediately after the processing shown by FIGS. 12-14 in the formation of the vertically-alternating tiers 20, 22 of insulative material 24 and memory cells MC, regardless of whether both trenches 25 and trenches 27 are formed or only one such plurality thereof is formed, and regardless of whether at least some material(s) of walls 80 and/or 84 remain(s) in the finished-circuitry construction.

Any other attribute(s) or aspect(s) as shown and/or described herein with respect to other embodiments may be used in the embodiments shown and described with reference to the above embodiments.

In one embodiment, a method used in forming memory circuitry (e.g., 10) comprises forming a lattice structure (e.g., 55) within semiconductor material (e.g., 12; e.g., regardless of whether forming lower walls 80 and/or 84). The lattice structure comprises insulative first vertical walls (e.g., 57) and insulative second vertical walls (e.g., 59) that cross laterally through one another below a top (e.g., 31) of the semiconductor material. The lattice structure comprises an insulative horizontal blanket layer (e.g., 35) that is vertically between and spaced from the top and a bottom (e.g., 37) of the semiconductor material. At least one of a plurality of the first vertical walls or a plurality of the second vertical walls are individually narrower (through its shortest straight-line horizontal dimension; e.g., W₁) at a top (e.g., 39) of the insulative horizontal blanket layer than at a bottom (e.g., 41) of the insulative horizontal blanket layer (through its shortest straight-line horizontal dimension; e.g., W₂). Vertically-alternating tiers (e.g., 20, 22) of insulative material (e.g., 24) and memory cells (e.g., MC) are directly above the semiconductor material. The memory cells individually comprise a capacitor (e.g., C) and a horizontally-oriented transistor (e.g., T).

In one embodiment, only one of the plurality of the first vertical walls or the plurality of the second vertical walls is narrower at the top of the insulative horizontal blanket layer than at the bottom of the insulative horizontal blanket layer. In another embodiment, each of the plurality of the first vertical walls and the plurality of the second vertical walls are narrower at the top of the insulative horizontal blanket layer than at the bottom of the insulative horizontal blanket layer.

Any other attribute(s) or aspect(s) as shown and/or described herein with respect to other embodiments may be used.

Alternate embodiment constructions may result from method embodiments described above, or otherwise. Regardless, embodiments of the invention encompass circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

In one embodiment, memory circuitry (e.g., 10) comprises vertically-alternating tiers (e.g., 20, 22) of insulative material (e.g., 24) and memory cells (e.g., MC). The memory cells individually comprise a capacitor (e.g., C) and a horizontally-oriented transistor (e.g., T). Semiconductor material (e.g., 12) is directly below the vertically-alternating tiers. A lattice structure (e.g., 55) is within the semiconductor material and comprises insulative first vertical walls (e.g., 57) and insulative second vertical walls (e.g., 59) that cross laterally through one another below a top (e.g., 31) of the semiconductor material. The lattice structure comprises an insulative horizontal blanket layer (e.g., 35) that is vertically between and spaced from the top and a bottom (e.g., 37) of the semiconductor material. At least one of a plurality of the first vertical walls or a plurality of the second vertical walls are individually narrower (through its shortest straight-line horizontal dimension; e.g., W₁) at a top (e.g., 39) of the insulative horizontal blanket layer than at a bottom (e.g., 41) of the insulative horizontal blanket layer.

In one embodiment, the insulative first and second vertical walls consist or consist essentially of the same insulator material. In one embodiment having both insulative walls 80 and 84, the insulative first vertical walls individually have a first average width (i.e., from top to bottom thereof within semiconductive material 12) and the insulative second vertical walls individually have a second average width (i.e., from top to bottom thereof within semiconductive material 12) that is different from first average width (e.g., walls 80 and walls 84 having different average widths; e.g., average width of walls 84 being greater than average width of walls 80).

Any other attribute(s) or aspect(s) as shown and/or described herein with respect to other embodiments may be used.

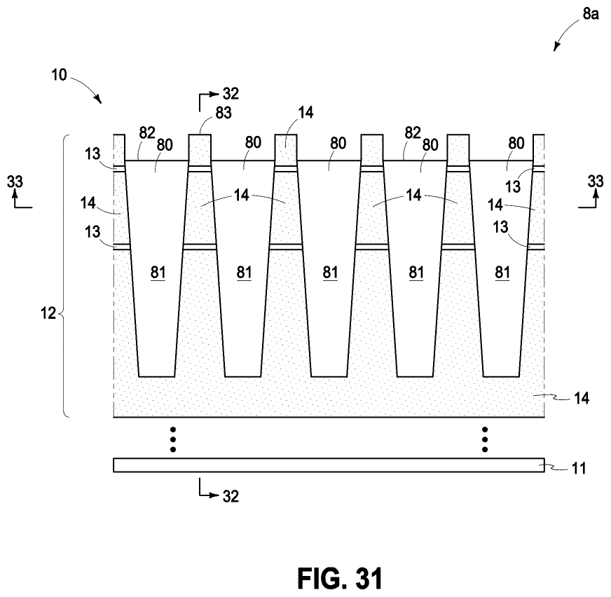

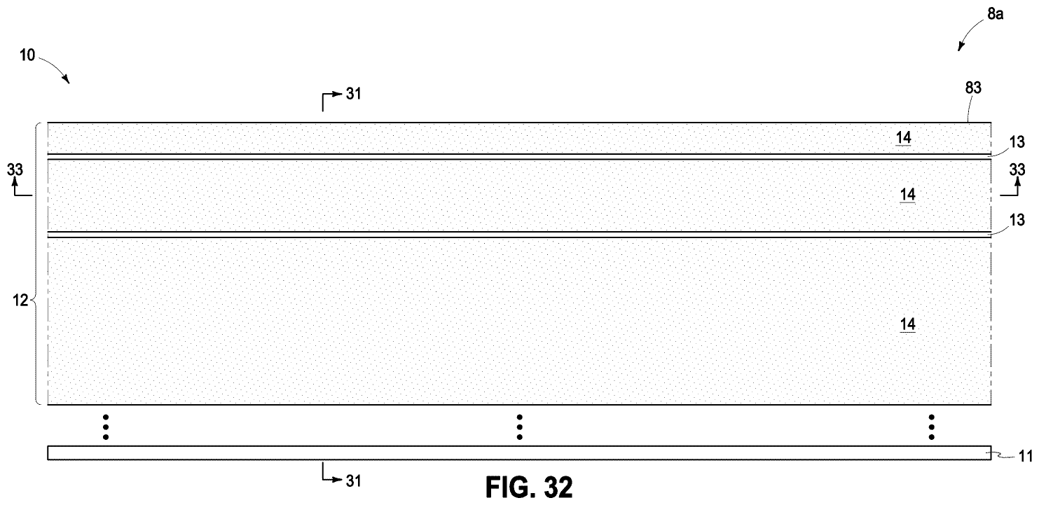

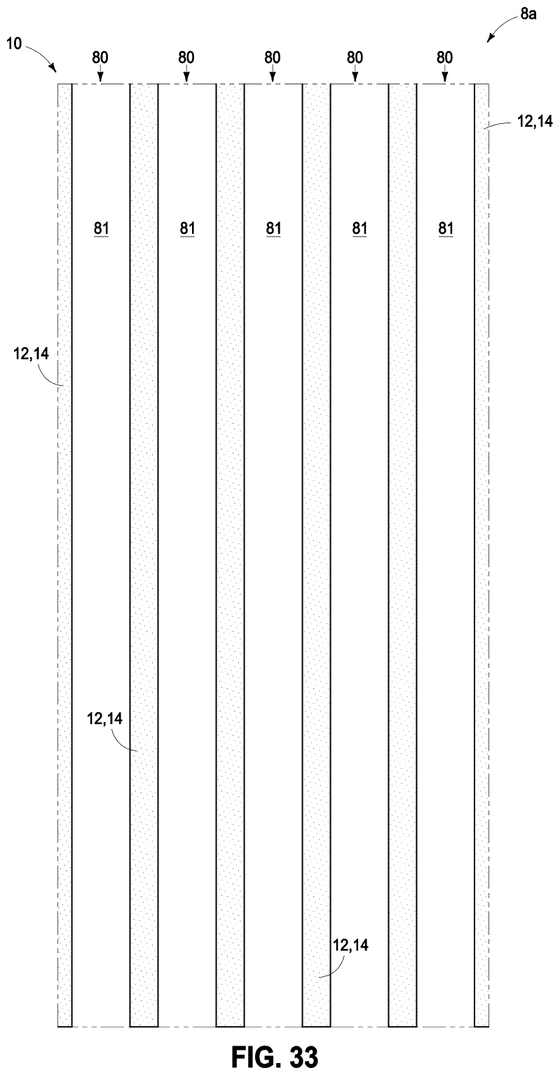

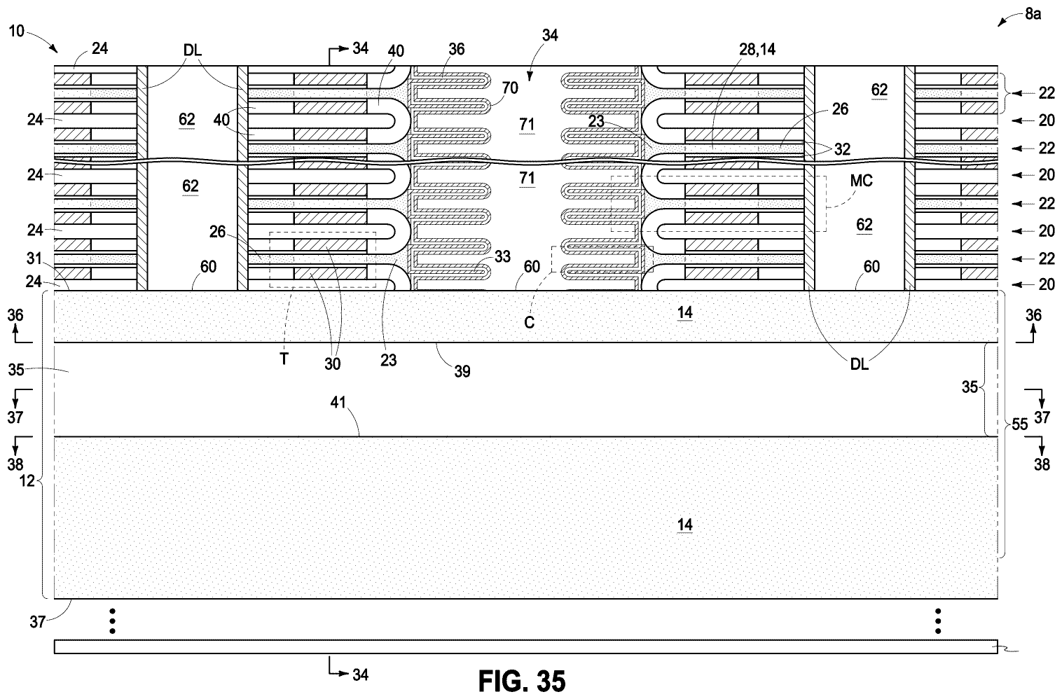

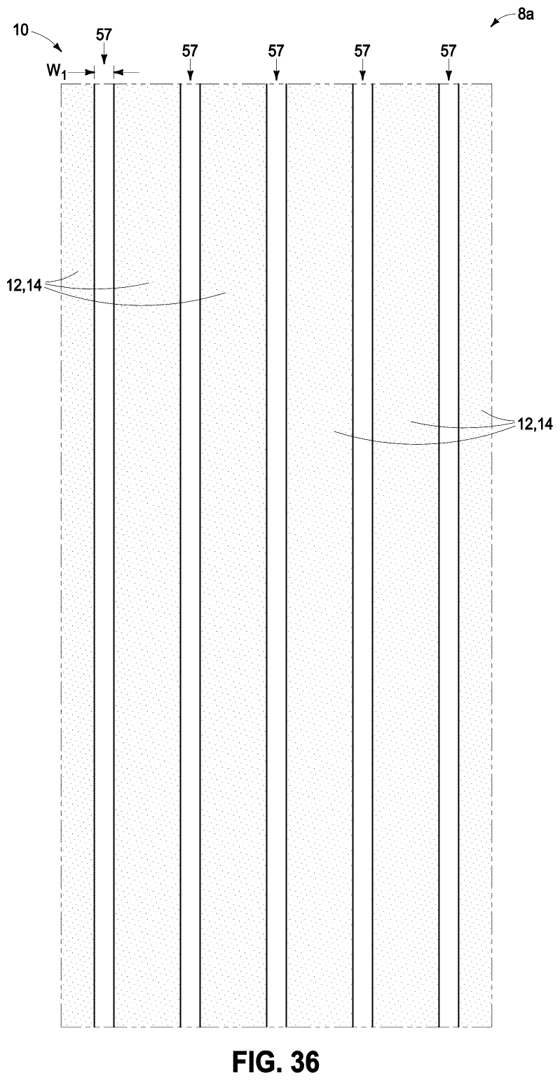

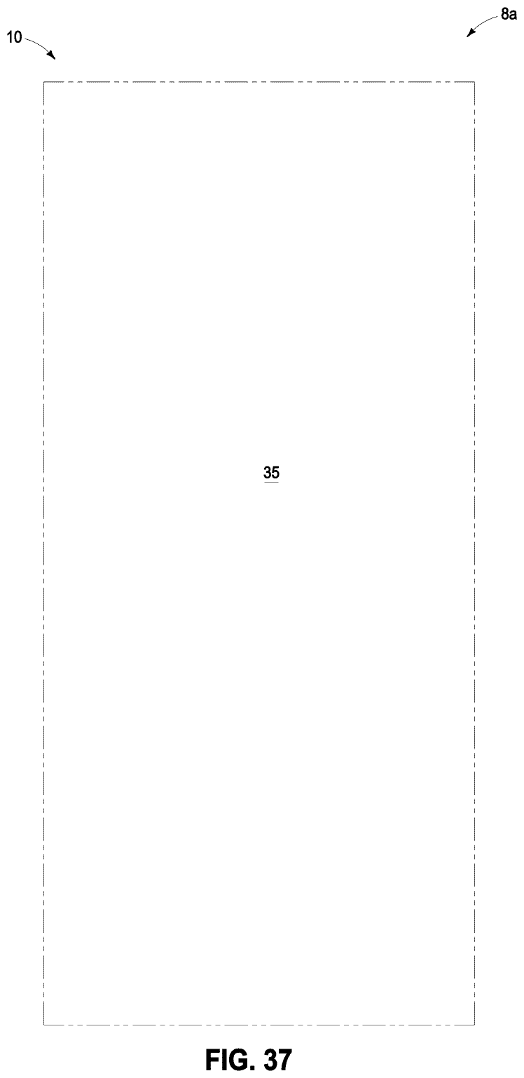

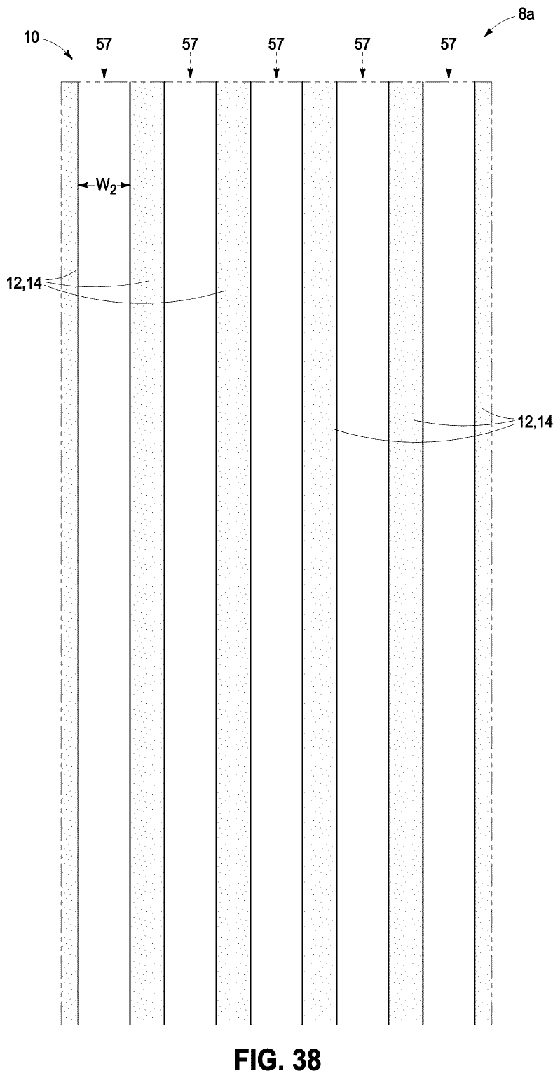

FIGS. 31-38 show an alternate embodiment construction 8a. Like numerals from the above-described embodiments have been used where appropriate, with some construction differences being indicated with the suffix “a” or with different numerals. FIGS. 31, 32, and 33 correspond to FIGS. 3, 4, and 6, respectively, in the first-described embodiment and show an example construction 8a comprising walls 80 but not walls 84. Alternately, and by way of example only, an example construction could have walls 84 but not walls 80 (not shown).

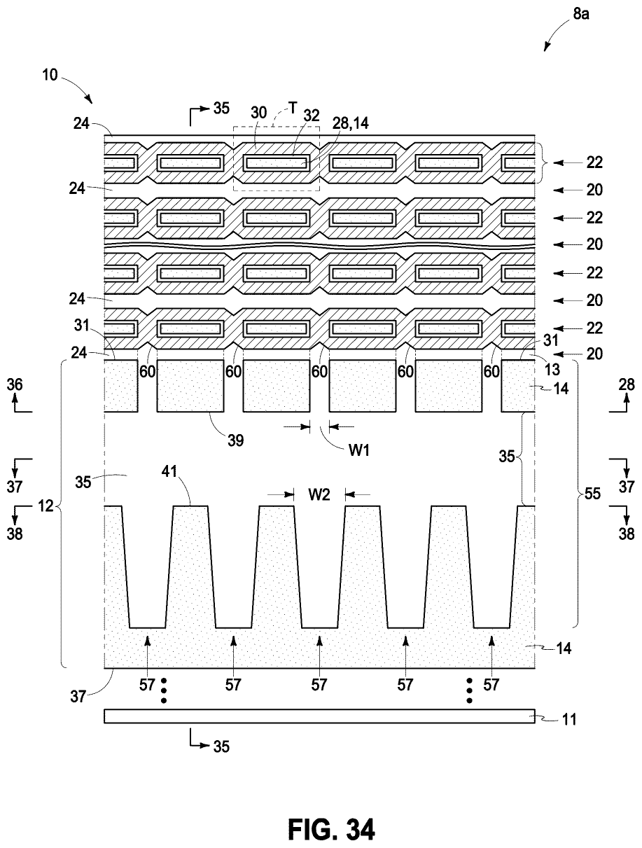

FIGS. 34-38 show construction 8a corresponding to that of FIGS. 26-30, respectively, comprising walls 57 but not walls 59.

Any other attribute(s) or aspect(s) as shown and/or described herein with respect to other embodiments may be used.

In some embodiments, memory circuitry (e.g., 10) comprises vertically-alternating tiers (e.g., 20 and 22) of insulative material (e.g., 24) and memory cells (e.g., MC). The memory cells individually comprise a capacitor (e.g., C) and a horizontally-oriented transistor (e.g., T). Semiconductor material (e.g., 12) is directly below the vertically-alternating tiers. Parallel and spaced insulative vertical walls are horizontally-elongated in the semiconductor material (e.g., walls 57 or walls 59 in FIGS. 26-30 regardless of the presence of the other; e.g., walls 57 in FIGS. 34-38). An insulative horizontal blanket layer (e.g., 35) is vertically between and spaced from a top (e.g., 31) and a bottom (e.g., 37) of the semiconductor material. The insulative vertical walls extend vertically through the insulative horizontal blanket layer. A plurality of the vertical walls individually are narrower at a top (e.g., 39) of the insulative horizontal blanket layer than at a bottom (e.g., 41) of the insulative horizontal blanket layer (e.g., W₁ and W₂ of walls 57 or W₁ and W₂ of walls 59 in FIGS. 26-30 regardless of the presence of the other; e.g., W₁ and W₂ of walls 57 in FIGS. 34-38). In one embodiment and as shown, the vertical walls individually have top (e.g., 60) that is elevationally at or above the top of the semiconductor material.

Any other attribute(s) or aspect(s) as shown and/or described herein with respect to other embodiments may be used.

Heretofore, example processing as described above in forming trenches 25 and/or 27 achieved depth thereof in semiconductor material 12 by a timed etch. Using wall material(s) 81 as an etch-stop may provide more precise control of depth of trenches 25 and/or 27 in semiconductor material 12.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming parallel and spaced lower walls in semiconductor material. Individual of the lower walls comprise wall material and have a top that is spaced below a top of the semiconductor material. Semiconductive material is epitaxially formed from the semiconductor material to cover over the individual lower walls. Vertically-alternating layers comprising silicon material and silicon-germanium material are epitaxially formed directly above the semiconductor material and the semiconductive-material-covered lower walls. Parallel and spaced trenches are etched through the vertically-alternating layers. The trenches are individually directly above and longitudinally along one of the individual lower walls. The trenches are etched to the individual lower walls and the wall material of the individual lower walls is used as an etch stop during such etching. After the etching, the silicon-germanium material is removed selectively relative to the silicon material and vertically-alternating tiers of insulative material and memory cells are formed. The memory cells individually comprise a capacitor and comprise a horizontally-oriented transistor having a channel comprising the epitaxially-formed silicon material.

In some embodiments, a method used in forming memory circuitry comprises forming a lattice structure within semiconductor material. The lattice structure comprises insulative first vertical walls and insulative second vertical walls that cross laterally through one another below a top of the semiconductor material. The lattice structure comprises an insulative horizontal blanket layer that is vertically between and spaced from the top and a bottom of the semiconductor material. At least one of a plurality of the first vertical walls or a plurality of the second vertical walls individually are narrower at a top of the insulative horizontal blanket layer than at a bottom of the insulative horizontal blanket layer. Vertically-alternating tiers of insulative material and memory cells are formed directly above the semiconductor material. The memory cells individually comprise a capacitor and a horizontally-oriented transistor.

In some embodiments, memory circuitry comprises vertically-alternating tiers of insulative material and memory cells. The memory cells individually comprise a capacitor and a horizontally-oriented transistor. Semiconductor material is directly below the vertically-alternating tiers. A lattice structure is within the semiconductor material. The lattice structure comprises insulative first vertical walls and insulative second vertical walls that cross laterally through one another below a top of the semiconductor material. The lattice structure comprises an insulative horizontal blanket layer that is vertically between and spaced from the top and a bottom of the semiconductor material. At least one of a plurality of the first vertical walls or a plurality of the second vertical walls individually are narrower at a top of the insulative horizontal blanket layer than at a bottom of the insulative horizontal blanket layer.

In some embodiments, memory circuitry comprises vertically-alternating tiers of insulative material and memory cells. The memory cells individually comprise a capacitor and a horizontally-oriented transistor. Semiconductor material is directly below the vertically-alternating tiers. Parallel and spaced insulative vertical walls are horizontally-elongated in the semiconductor material. An insulative horizontal blanket layer is vertically between and spaced from a top and a bottom of the semiconductor material. The insulative vertical walls extend vertically through the insulative horizontal blanket layer. A plurality of the vertical walls are individually narrower at a top of the insulative horizontal blanket layer than at a bottom of the insulative horizontal blanket layer.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming parallel and spaced lower walls in semiconductor material, individual of the lower walls comprising wall material and having a top that is spaced below a top of the semiconductor material;
epitaxially forming semiconductive material from the semiconductor material to cover over the individual lower walls;
epitaxially forming vertically-alternating layers comprising silicon material and silicon-germanium material directly above the semiconductor material and the semiconductive-material-covered lower walls;
etching parallel and spaced trenches through the vertically-alternating layers, the trenches individually being directly above and longitudinally along one of the individual lower walls, the trenches being etched to the individual lower walls and using the wall material of the individual lower walls as an etch stop during such etching; and
after the etching, removing the silicon-germanium material selectively relative to the silicon material and forming vertically-alternating tiers of insulative material and memory cells, the memory cells individually comprising a capacitor and comprising a horizontally-oriented transistor having a channel comprising the epitaxially-formed silicon material.

2. The method of claim 1 wherein a bottom of individual of the trenches is narrower than the top of the individual lower wall to which such individual trench is etched.

3. The method of claim 1 wherein at least some of the lower walls remain in a finished-circuitry construction.

4. The method of claim 1 wherein none of the lower walls remain in a finished-circuitry construction.

5. The method of claim 4 wherein, after the etching, removing the lower walls by etching all of the wall material through the trenches.

6. The method of claim 5 wherein the lower walls are removed before forming the vertically-alternating tiers of the insulative material and the memory cells.

7. The method of claim 6 wherein the lower walls are removed before removing the silicon-germanium material selectively relative to the silicon material.

8. The method of claim 1 wherein the wall material and the lower walls are insulative.

9. The method of claim 1 wherein the wall material and the lower walls are at least one of conductive or semiconductive.

10. The method of claim 9 wherein, after the etching, removing the lower walls by etching all of the wall material through the trenches.

11. The method of claim 1 wherein the semiconductor material comprises two vertically-spaced layers of silicon-germanium material having silicon material vertically there-between.

12. The method of claim 11 comprising etching away the two vertically-spaced layers of silicon-germanium material selectively relative to the silicon material vertically there-between, followed by etching away the silicon material that was vertically between the two vertically-spaced layers of silicon-germanium material.

13. The method of claim 12 wherein after etching the two vertically-spaced layers of silicon-germanium material and then the silicon material that was vertically there-between, further comprising:
forming a lattice structure within the semiconductor material, the lattice structure comprising insulative first vertical walls and insulative second vertical walls that cross laterally through one another below a top of the semiconductor material, the lattice structure comprising an insulative horizontal blanket layer where the two vertically-spaced layers of silicon-germanium material and the silicon material there-between were and that is vertically between and spaced from the top and a bottom of the semiconductor material; and
at least one of a plurality of the first vertical walls or a plurality of the second vertical walls individually being narrower at a top of the insulative horizontal blanket layer than at a bottom of the insulative horizontal blanket layer.

14. A method used in forming memory circuitry, comprising:
forming a lattice structure within semiconductor material, the lattice structure comprising insulative first vertical walls and insulative second vertical walls that cross laterally through one another below a top of the semiconductor material, the lattice structure comprising an insulative horizontal blanket layer that is vertically between and spaced from the top and a bottom of the semiconductor material;
at least one of a plurality of the first vertical walls or a plurality of the second vertical walls individually being narrower at a top of the insulative horizontal blanket layer than at a bottom of the insulative horizontal blanket layer; and
forming vertically-alternating tiers of insulative material and memory cells directly above the semiconductor material, the memory cells individually comprising a capacitor and a horizontally-oriented transistor.

15. The method of claim 14 wherein only one of the plurality of the first vertical walls or the plurality of the second vertical walls is narrower at the top of the insulative horizontal blanket layer than at the bottom of the insulative horizontal blanket layer.

16. The method of claim 14 wherein each of the plurality of the first vertical walls and the plurality of the second vertical walls are narrower at the top of the insulative horizontal blanket layer than at the bottom of the insulative horizontal blanket layer.

17. Memory circuitry comprising:
vertically-alternating tiers of insulative material and memory cells, the memory cells individually comprising a capacitor and a horizontally-oriented transistor;
semiconductor material directly below the vertically-alternating tiers;
a lattice structure within the semiconductor material, the lattice structure comprising insulative first vertical walls and insulative second vertical walls that cross laterally through one another below a top of the semiconductor material, the lattice structure comprising an insulative horizontal blanket layer that is vertically between and spaced from the top and a bottom of the semiconductor material; and
at least one of a plurality of the first vertical walls or a plurality of the second vertical walls individually being narrower at a top of the insulative horizontal blanket layer than at a bottom of the insulative horizontal blanket layer.

18. The memory circuitry of claim 17 wherein only one of the plurality of the first vertical walls or the plurality of the second vertical walls is narrower at the top of the insulative horizontal blanket layer than at the bottom of the insulative horizontal blanket layer.

19. The memory circuitry of claim 17 wherein each of the plurality of the first vertical walls or the plurality of the second vertical walls is narrower at the top of the insulative horizontal blanket layer than at the bottom of the insulative horizontal blanket layer.

20. Memory circuitry comprising:
vertically-alternating tiers of insulative material and memory cells, the memory cells individually comprising a capacitor and a horizontally-oriented transistor;
semiconductor material directly below the vertically-alternating tiers;
parallel and spaced insulative vertical walls that are horizontally-elongated in the semiconductor material;
an insulative horizontal blanket layer that is vertically between and spaced from a top and a bottom of the semiconductor material, the insulative vertical walls extending vertically through the insulative horizontal blanket layer; and
a plurality of the vertical walls individually being narrower at a top of the insulative horizontal blanket layer than at a bottom of the insulative horizontal blanket layer.
